(19) United States
(12) Patent Application Publication
(10) Pub. No.: US 2023/0406362 A1
(43) Pub. Date: Dec. 21, 2023

(54) PLANNING-IMPACTED PREDICTION EVALUATION

(71) Applicant: Baidu USA LLC, Sunnyvale, CA (US)

(72) Inventors: Shu JIANG, Sunnyvale, CA (US); Szu Hao WU, Sunnyvale, CA (US); Yu CAO, Sunnyvale, CA (US); Weiman LIN, Sunnyvale, CA (US); Jiangtao HU, Sunnyvale, CA (US); Ang LI, Sunnyvale, CA (US)

(21) Appl. No.: 17/841,330

(22) Filed: Jun. 15, 2022

(51) Int. Cl. B60W 60/00; B60W 30/095

(52) U.S. Cl. CPC B60W 60/00274; B60W 60/0011; B60W 60/0015; B60W 30/095; B60W 2555/60; B60W 2556/20; B60W 2554/801; B60W 2554/802

(57) ABSTRACT

A plurality of trajectories of a plurality of obstacles are predicted, at an autonomous driving simulation platform, by a prediction module of an autonomous driving vehicle (ADV). A trajectory of the ADV is planned, at the autonomous driving simulation platform, by a planning module of the ADV based on the plurality of trajectories of the plurality of obstacles. A performance of the planning module is determined based on one or more evaluation metrics regarding the trajectory of the ADV. A performance of the prediction module is evaluated based on the performance of the planning module to improve the performance of the prediction module to deploy the prediction module to the ADV to drive autonomously.

### TECHNICAL FIELD

Embodiments of the present disclosure relate generally to autonomous driving vehicles. More particularly, embodiments of the disclosure relate to evaluating the performance of an autonomous driving vehicle (ADV).

### BACKGROUND

Vehicles operating in an autonomous mode (e.g., driverless) can relieve occupants, especially the driver, from some driving-related responsibilities. When operating in an autonomous mode, the vehicle can navigate to various locations using onboard sensors, allowing the vehicle to travel with minimal human interaction or in some cases without any passengers.

Motion planning and control are critical operations in autonomous driving. An ADV may have a prediction module which predicts the trajectories of one or more obstacles under the driving circumstances and a planning module which plans a path or route for the ADV, as well as driving parameters (e.g., distance, speed, and/or turning angle), based on the trajectories of the one or more obstacles. The prediction module is an upstream module of the planning module in autonomous driving. The performance of the prediction module is currently evaluated only by the accuracy of the trajectories of the one or more obstacles. However, since the requirements of the planning module are not included in the performance evaluation of the prediction module, the improvement of the performance of the prediction module may not contribute to an improvement of the performance of the planning module.

### BRIEF DESCRIPTION OF THE DRAWINGS

Embodiments of the disclosure are illustrated by way of example and not limitation in the figures of the accompanying drawings in which like references indicate similar elements.

FIG. 1 is a block diagram illustrating a networked system according to one embodiment.

FIG. 2 is a block diagram illustrating an example of an autonomous driving vehicle according to one embodiment.

FIGS. 3A-3B are block diagrams illustrating an example of an autonomous driving system used with an autonomous driving vehicle according to one embodiment.

FIGS. 4A-4B are block diagrams illustrating an example of an autonomous driving simulation platform of an autonomous driving system according to one embodiment.

FIG. 5 is a block diagram illustrating an example of a process of evaluating a prediction module of an autonomous driving vehicle at an autonomous driving simulation platform according to one embodiment.

FIG. 6 is a diagram illustrating an example of evaluating a prediction module of an autonomous driving vehicle according to one embodiment.

FIG. 7 is a flow diagram illustrating a method of evaluating a prediction module of an autonomous driving vehicle according to one embodiment.

### DETAILED DESCRIPTION

Various embodiments and aspects of the disclosures will be described with reference to details discussed below, and the accompanying drawings will illustrate the various embodiments. The following description and drawings are illustrative of the disclosure and are not to be construed as limiting the disclosure. Numerous specific details are described to provide a thorough understanding of various embodiments of the present disclosure. However, in certain instances, well-known or conventional details are not described in order to provide a concise discussion of embodiments of the present disclosures.

Reference in the specification to “one embodiment” or “an embodiment” means that a particular feature, structure, or characteristic described in conjunction with the embodiment can be included in at least one embodiment of the disclosure. The appearances of the phrase “in one embodiment” in various places in the specification do not necessarily all refer to the same embodiment.

According to some embodiments, an evaluation method and system for a prediction module of an ADV aiming to improve the overall performance of the ADV is disclosed. The performance of the prediction module is evaluated based on the performance of the planning module. For example, the performance of the planning module may be determined by a set of metrics, including a collision, a comfort level, a violation of traffic rules, or a near collision of a planned trajectory. Based on the performance of the planning module, a loss function of an analysis model may be designed and a structure of the analysis model may be changed. The prediction module may be trained based on the analysis model. In this way, the overall performance of the ADV is improved with the improvement of the performance of the prediction module, thereby improving the safety and reliability of the ADV.

According to some embodiments, a plurality of trajectories of a plurality of obstacles are predicted, at an autonomous driving simulation platform, by a prediction module of an autonomous driving system (ADS) of an ADV. A trajectory of the ADV is planned, at the autonomous driving simulation platform, by a planning module of the ADV based on the plurality of trajectories of the plurality of obstacles. A performance of the planning module is determined based on one or more evaluation metrics regarding the trajectory of the ADV. A performance of the prediction module is evaluated based on the performance of the planning module to improve the performance of the prediction module to deploy the prediction module to the ADV to drive autonomously.

According to some embodiments, a non-transitory machine-readable medium having instructions stored therein is disclosed. The instructions, when executed by a processor, cause the processor to predict, at an autonomous driving simulation platform, a plurality of trajectories of a plurality of obstacles by a prediction module of an ADV; plan, at the autonomous driving simulation platform, a trajectory of the ADV by a planning module of the ADV based on the plurality of trajectories of the plurality of obstacles; determine a performance of the planning module based on one or more evaluation metrics regarding the trajectory of the ADV; and evaluate a performance of the prediction module based on the performance of the planning module to improve the performance of the prediction module to deploy the prediction module to the ADV to drive autonomously.

According to some embodiments, a data processing system is disclosed. The data processing system comprises a processor; and a memory coupled to the processor to store instructions. The instructions, when executed by a processor, cause the processor to predict, at an autonomous driving simulation platform, a plurality of trajectories of a plurality of obstacles by a prediction module of an ADV; plan, at the autonomous driving simulation platform, a trajectory of the ADV by a planning module of the ADV based on the plurality of trajectories of the plurality of obstacles; determine a performance of the planning module based on one or more evaluation metrics regarding the trajectory of the ADV; and evaluate a performance of the prediction module based on the performance of the planning module to improve the performance of the prediction module to deploy the prediction module to the ADS of the ADV to drive autonomously.

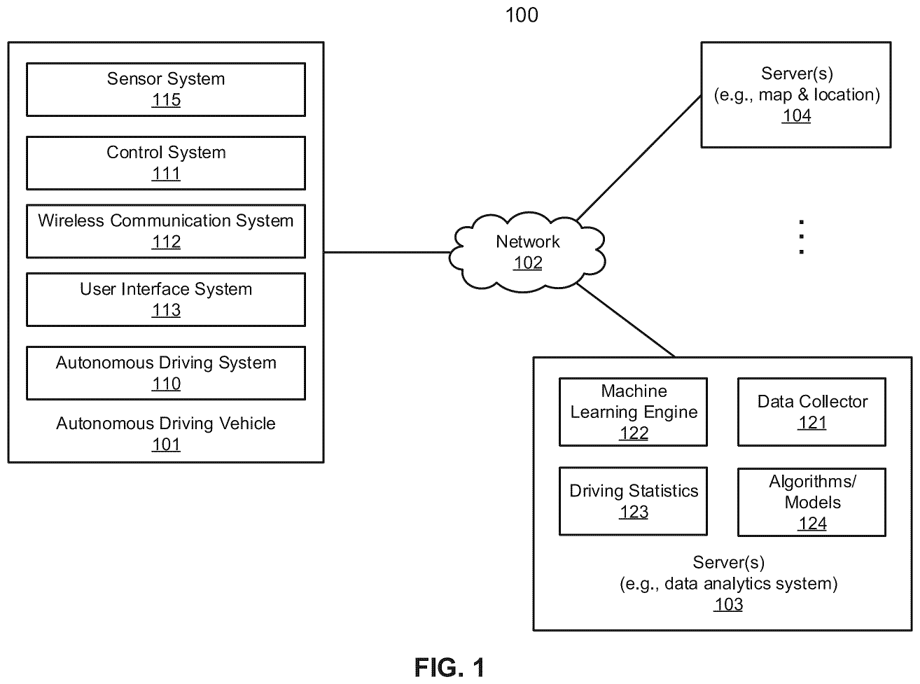

FIG. 1 is a block diagram illustrating an autonomous driving network configuration according to one embodiment of the disclosure. Referring to FIG. 1, network configuration 100 includes autonomous driving vehicle (ADV) 101 that may be communicatively coupled to one or more servers 103-104 over a network 102. Although there is one ADV shown, multiple ADVs can be coupled to each other and/or coupled to servers 103-104 over network 102. Network 102 may be any type of networks such as a local area network (LAN), a wide area network (WAN) such as the Internet, a cellular network, a satellite network, or a combination thereof, wired or wireless. Server(s) 103-104 may be any kind of servers or a cluster of servers, such as Web or cloud servers, application servers, backend servers, or a combination thereof. Servers 103-104 may be data analytics servers, content servers, traffic information servers, map and point of interest (MPOI) servers, or location servers, etc.

An ADV refers to a vehicle that can be configured to in an autonomous mode in which the vehicle navigates through an environment with little or no input from a driver. Such an ADV can include a sensor system having one or more sensors that are configured to detect information about the environment in which the vehicle operates. The vehicle and its associated controller(s) use the detected information to navigate through the environment. ADV 101 can operate in a manual mode, a full autonomous mode, or a partial autonomous mode.

In one embodiment, ADV 101 includes, but is not limited to, autonomous driving system (ADS) 110, vehicle control system 111, wireless communication system 112, user interface system 113, and sensor system 115. ADV 101 may further include certain common components included in ordinary vehicles, such as, an engine, wheels, steering wheel, transmission, etc., which may be controlled by vehicle control system 111 and/or ADS 110 using a variety of communication signals and/or commands, such as, for example, acceleration signals or commands, deceleration signals or commands, steering signals or commands, braking signals or commands, etc.

Components 110-115 may be communicatively coupled to each other via an interconnect, a bus, a network, or a combination thereof. For example, components 110-115 may be communicatively coupled to each other via a controller area network (CAN) bus. A CAN bus is a vehicle bus standard designed to allow microcontrollers and devices to communicate with each other in applications without a host computer. It is a message-based protocol, designed originally for multiplex electrical wiring within automobiles, but is also used in many other contexts.

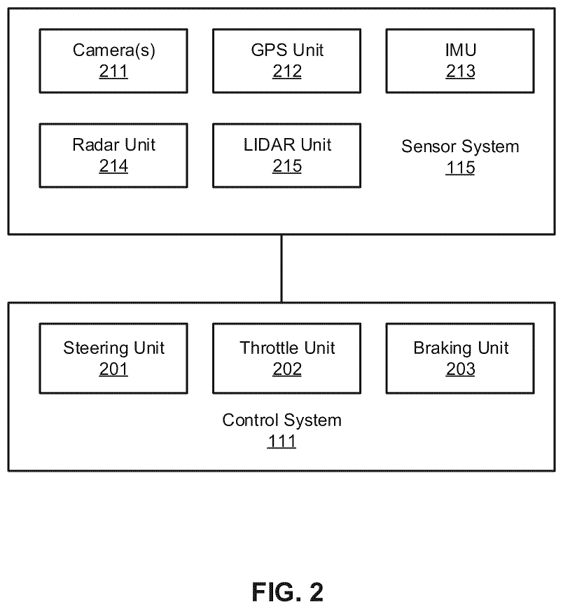

Referring now to FIG. 2, in one embodiment, sensor system 115 includes, but it is not limited to, one or more cameras 211, global positioning system (GPS) unit 212, inertial measurement unit (IMU) 213, radar unit 214, and a light detection and range (LIDAR) unit 215. GPS system 212 may include a transceiver operable to provide information regarding the position of the ADV. IMU unit 213 may sense position and orientation changes of the ADV based on inertial acceleration. Radar unit 214 may represent a system that utilizes radio signals to sense objects within the local environment of the ADV. In some embodiments, in addition to sensing objects, radar unit 214 may additionally sense the speed and/or heading of the objects. LIDAR unit 215 may sense objects in the environment in which the ADV is located using lasers. LIDAR unit 215 could include one or more laser sources, a laser scanner, and one or more detectors, among other system components. Cameras 211 may include one or more devices to capture images of the environment surrounding the ADV. Cameras 211 may be still cameras and/or video cameras. A camera may be mechanically movable, for example, by mounting the camera on a rotating and/or tilting a platform.

Sensor system 115 may further include other sensors, such as, a sonar sensor, an infrared sensor, a steering sensor, a throttle sensor, a braking sensor, and an audio sensor (e.g., microphone). An audio sensor may be configured to capture sound from the environment surrounding the ADV. A steering sensor may be configured to sense the steering angle of a steering wheel, wheels of the vehicle, or a combination thereof. A throttle sensor and a braking sensor sense the throttle position and braking position of the vehicle, respectively. In some situations, a throttle sensor and a braking sensor may be integrated as an integrated throttle/braking sensor.

In one embodiment, vehicle control system 111 includes, but is not limited to, steering unit 201, throttle unit 202 (also referred to as an acceleration unit), and braking unit 203. Steering unit 201 is to adjust the direction or heading of the vehicle. Throttle unit 202 is to control the speed of the motor or engine that in turn controls the speed and acceleration of the vehicle. Braking unit 203 is to decelerate the vehicle by providing friction to slow the wheels or tires of the vehicle. Note that the components as shown in FIG. 2 may be implemented in hardware, software, or a combination thereof.

Referring back to FIG. 1, wireless communication system 112 is to allow communication between ADV 101 and external systems, such as devices, sensors, other vehicles, etc. For example, wireless communication system 112 can wirelessly communicate with one or more devices directly or via a communication network, such as servers 103-104 over network 102. Wireless communication system 112 can use any cellular communication network or a wireless local area network (WLAN), e.g., using WiFi to communicate with another component or system. Wireless communication system 112 could communicate directly with a device (e.g., a mobile device of a passenger, a display device, a speaker within vehicle 101), for example, using an infrared link, Bluetooth, etc. User interface system 113 may be part of peripheral devices implemented within vehicle 101 including, for example, a keyboard, a touch screen display device, a microphone, and a speaker, etc.

Some or all of the functions of ADV 101 may be controlled or managed by ADS 110, especially when operating in an autonomous driving mode. ADS 110 includes the necessary hardware (e.g., processor(s), memory, storage) and software (e.g., operating system, planning and routing programs) to receive information from sensor system 115, control system 111, wireless communication system 112, and/or user interface system 113, process the received information, plan a route or path from a starting point to a destination point, and then drive vehicle 101 based on the planning and control information. Alternatively, ADS 110 may be integrated with vehicle control system 111.

For example, a user as a passenger may specify a starting location and a destination of a trip, for example, via a user interface. ADS 110 obtains the trip related data. For example, ADS 110 may obtain location and route data from an MPOI server, which may be a part of servers 103-104. The location server provides location services and the MPOI server provides map services and the POIs of certain locations. Alternatively, such location and MPOI information may be cached locally in a persistent storage device of ADS 110.

While ADV 101 is moving along the route, ADS 110 may also obtain real-time traffic information from a traffic information system or server (TIS). Note that servers 103-104 may be operated by a third party entity. Alternatively, the functionalities of servers 103-104 may be integrated with ADS 110. Based on the real-time traffic information, MPOI information, and location information, as well as real-time local environment data detected or sensed by sensor system 115 (e.g., obstacles, objects, nearby vehicles), ADS 110 can plan an optimal route and drive vehicle 101, for example, via control system 111, according to the planned route to reach the specified destination safely and efficiently.

Server 103 may be a data analytics system to perform data analytics services for a variety of clients. In one embodiment, data analytics system 103 includes data collector 121 and machine learning engine 122. Data collector 121 collects driving statistics 123 from a variety of vehicles, either ADVs or regular vehicles driven by human drivers. Driving statistics 123 include information indicating the driving commands (e.g., throttle, brake, steering commands) issued and responses of the vehicles (e.g., speeds, accelerations, decelerations, directions) captured by sensors of the vehicles at different points in time. Driving statistics 123 may further include information describing the driving environments at different points in time, such as, for example, routes (including starting and destination locations), MPOIs, road conditions, weather conditions, etc.

Based on driving statistics 123, machine learning engine 122 generates or trains a set of rules, algorithms, and/or predictive models 124 for a variety of purposes. Algorithms 124 can then be uploaded on ADVs to be utilized during autonomous driving in real-time.

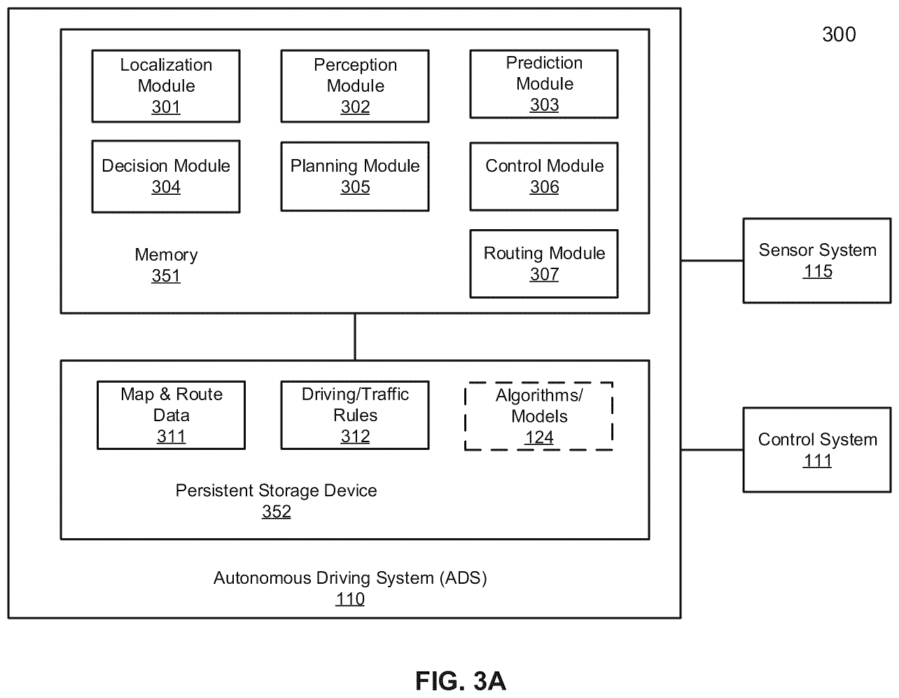

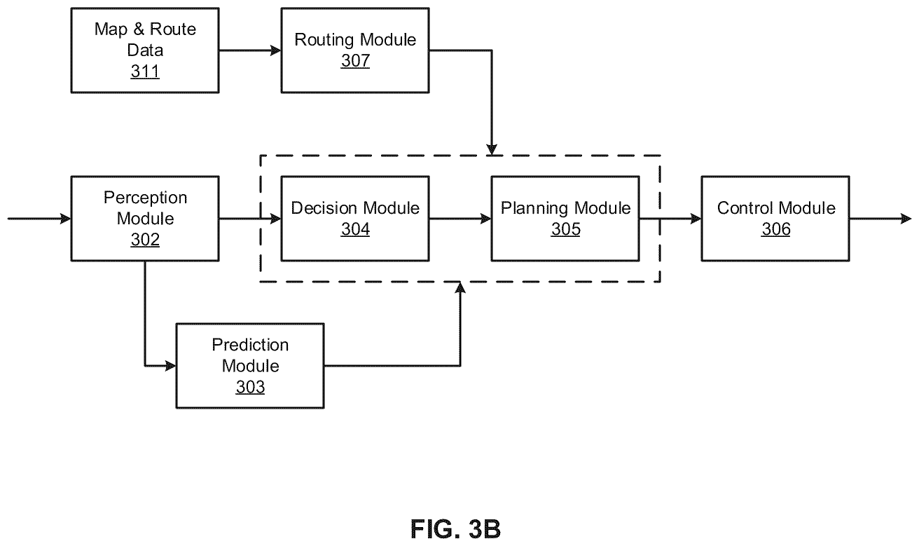

FIGS. 3A and 3B are block diagrams illustrating an example of an autonomous driving system used with an ADV according to one embodiment. System 300 may be implemented as a part of ADV 101 of FIG. 1 including, but is not limited to, ADS 110, control system 111, and sensor system 115. Referring to FIGS. 3A-3B, ADS 110 includes, but is not limited to, localization module 301, perception module 302, prediction module 303, decision module 304, planning module 305, control module 306, and routing module 307.

Some or all of modules 301-307 may be implemented in software, hardware, or a combination thereof. For example, these modules may be installed in persistent storage device 352, loaded into memory 351, and executed by one or more processors (not shown). Note that some or all of these modules may be communicatively coupled to or integrated with some or all modules of vehicle control system 111 of FIG. 2. Some of modules 301-307 may be integrated together as an integrated module.

Localization module 301 determines a current location of ADV 300 (e.g., leveraging GPS unit 212) and manages any data related to a trip or route of a user. Localization module 301 (also referred to as a map and route module) manages any data related to a trip or route of a user. A user may log in and specify a starting location and a destination of a trip, for example, via a user interface. Localization module 301 communicates with other components of ADV 300, such as map and route data 311, to obtain the trip related data. For example, localization module 301 may obtain location and route data from a location server and a map and POI (MPOI) server. A location server provides location services and an MPOI server provides map services and the POIs of certain locations, which may be cached as part of map and route data 311. While ADV 300 is moving along the route, localization module 301 may also obtain real-time traffic information from a traffic information system or server.

Based on the sensor data provided by sensor system 115 and localization information obtained by localization module 301, a perception of the surrounding environment is determined by perception module 302. The perception information may represent what an ordinary driver would perceive surrounding a vehicle in which the driver is driving. The perception can include the lane configuration, traffic light signals, a relative position of another vehicle, a pedestrian, a building, crosswalk, or other traffic related signs (e.g., stop signs, yield signs), etc., for example, in a form of an object. The lane configuration includes information describing a lane or lanes, such as, for example, a shape of the lane (e.g., straight or curvature), a width of the lane, how many lanes in a road, one-way or two-way lane, merging or splitting lanes, exiting lane, etc.

Perception module 302 may include a computer vision system or functionalities of a computer vision system to process and analyze images captured by one or more cameras in order to identify objects and/or features in the environment of the ADV. The objects can include traffic signals, road way boundaries, other vehicles, pedestrians, and/or obstacles, etc. The computer vision system may use an object recognition algorithm, video tracking, and other computer vision techniques. In some embodiments, the computer vision system can map an environment, track objects, and estimate the speed of objects, etc. Perception module 302 can also detect objects based on other sensors data provided by other sensors such as a radar and/or LIDAR.

For each of the objects, prediction module 303 predicts what the object will behave under the circumstances. For example, prediction module 303 predicts a trajectory of the object. The prediction is performed based on the perception data perceiving the driving environment at the point in time in view of a set of map/rout information 311 and traffic rules 312. For example, if the object is a vehicle at an opposing direction and the current driving environment includes an intersection, prediction module 303 will predict whether the vehicle will likely move straight forward or make a turn. If the perception data indicates that the intersection has no traffic light, prediction module 303 may predict that the vehicle may have to fully stop prior to enter the intersection. If the perception data indicates that the vehicle is currently at a left-turn only lane or a right-turn only lane, prediction module 303 may predict that the vehicle will more likely make a left turn or right turn respectively.

For each of the objects, decision module 304 makes a decision regarding how to handle the object. For example, for a particular object (e.g., another vehicle in a crossing route) as well as its metadata describing the object (e.g., a speed, direction, turning angle), decision module 304 decides how to encounter the object (e.g., overtake, yield, stop, pass). Decision module 304 may make such decisions according to a set of rules such as traffic rules or driving rules 312, which may be stored in persistent storage device 352.

Routing module 307 is configured to provide one or more routes or paths from a starting point to a destination point. For a given trip from a start location to a destination location, for example, received from a user, routing module 307 obtains route and map information 311 and determines all possible routes or paths from the starting location to reach the destination location. Routing module 307 may generate a reference line in a form of a topographic map for each of the routes it determines from the starting location to reach the destination location. A reference line refers to an ideal route or path without any interference from others such as other vehicles, obstacles, or traffic condition. That is, if there is no other vehicle, pedestrians, or obstacles on the road, an ADV should exactly or closely follows the reference line. The topographic maps are then provided to decision module 304 and/or planning module 305. Decision module 304 and/or planning module 305 examine all of the possible routes to select and modify one of the most optimal routes in view of other data provided by other modules such as traffic conditions from localization module 301, driving environment perceived by perception module 302, and traffic condition predicted by prediction module 303. The actual path or route for controlling the ADV may be close to or different from the reference line provided by routing module 307 dependent upon the specific driving environment at the point in time.

Based on a decision for each of the objects perceived, planning module 305 plans a trajectory or a path or route for the ADV, as well as driving parameters (e.g., distance, speed, and/or turning angle), using a reference line provided by routing module 307 as a basis. That is, for a given object, decision module 304 decides what to do with the object, while planning module 305 determines how to do it. For example, for a given object, decision module 304 may decide to pass the object, while planning module 305 may determine whether to pass on the left side or right side of the object. Planning and control data is generated by planning module 305 including information describing how vehicle 300 would move in a next moving cycle (e.g., next route/path segment). For example, the planning and control data may instruct vehicle 300 to move 10 meters at a speed of 30 miles per hour (mph), then change to a right lane at the speed of 25 mph.

Based on the planning and control data, control module 306 controls and drives the ADV, by sending proper commands or signals to vehicle control system 111, according to a trajectory or a route or path defined by the planning and control data. The planning and control data include sufficient information to drive the vehicle from a first point to a second point of a route or path using appropriate vehicle settings or driving parameters (e.g., throttle, braking, steering commands) at different points in time along the path or route.

In one embodiment, the planning phase is performed in a number of planning cycles, also referred to as driving cycles, such as, for example, in every time interval of 100 milliseconds (ms). For each of the planning cycles or driving cycles, one or more control commands will be issued based on the planning and control data. That is, for every 100 ms, planning module 305 plans a next route segment or path segment, for example, including a target position and the time required for the ADV to reach the target position. Alternatively, planning module 305 may further specify the specific speed, direction, and/or steering angle, etc. In one embodiment, planning module 305 plans a route segment or path segment for the next predetermined period of time such as 5 seconds. For each planning cycle, planning module 305 plans a target position for the current cycle (e.g., next 5 seconds) based on a target position planned in a previous cycle. Control module 306 then generates one or more control commands (e.g., throttle, brake, steering control commands) based on the planning and control data of the current cycle.

Note that decision module 304 and planning module 305 may be integrated as an integrated module. Decision module 304/planning module 305 may include a navigation system or functionalities of a navigation system to determine a driving path for the ADV. For example, the navigation system may determine a series of speeds and directional headings to affect movement of the ADV along a path that substantially avoids perceived obstacles while generally advancing the ADV along a roadway-based path leading to an ultimate destination. The destination may be set according to user inputs via user interface system 113. The navigation system may update the driving path dynamically while the ADV is in operation. The navigation system can incorporate data from a GPS system and one or more maps so as to determine the driving path for the ADV.

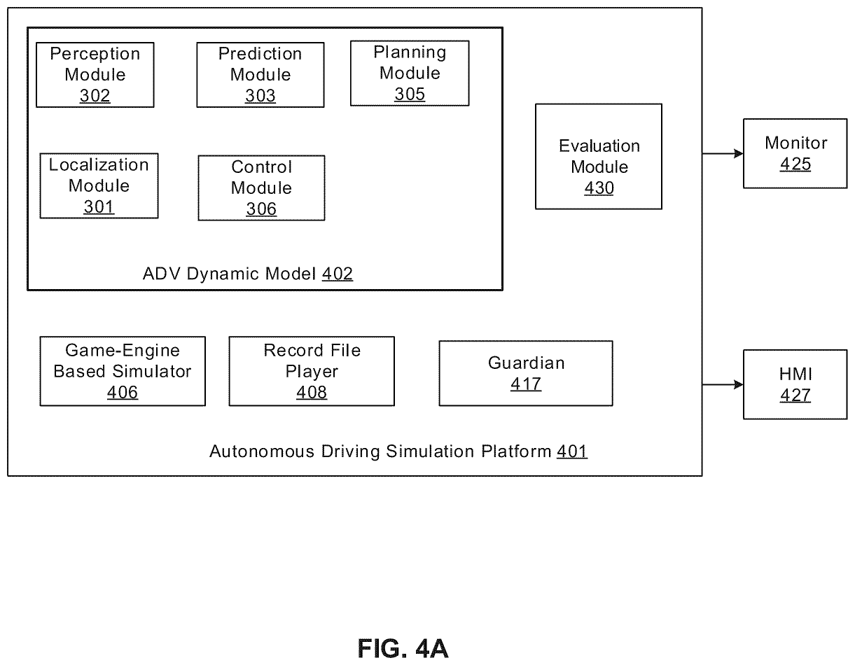

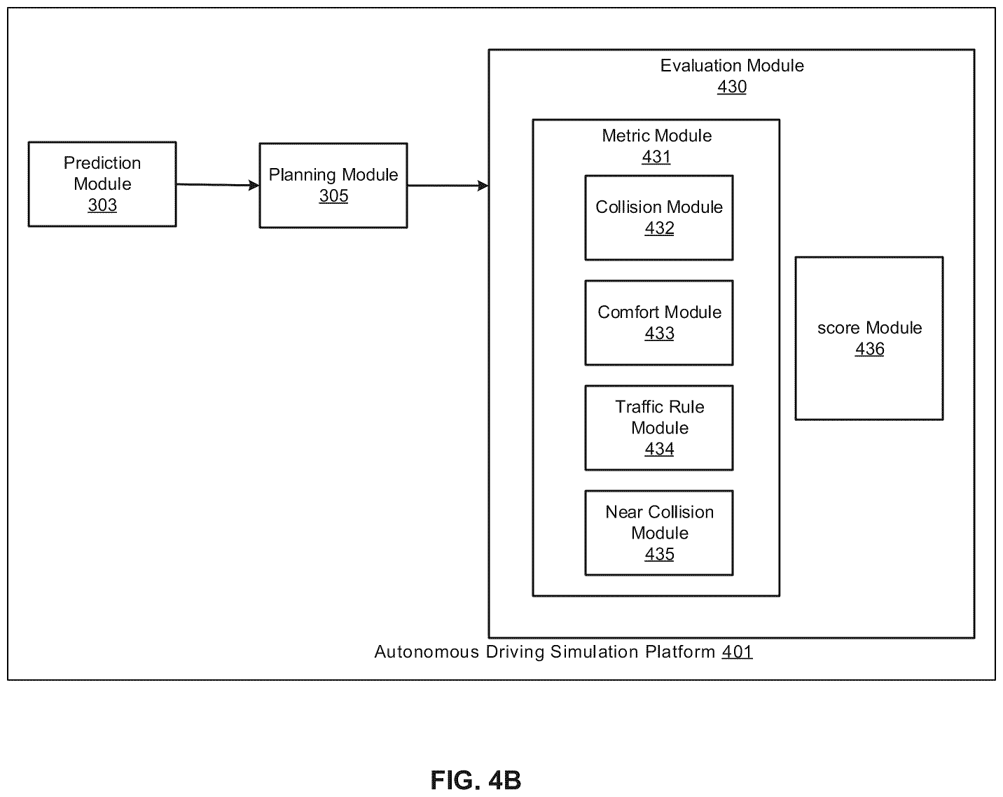

FIGS. 4A-4B are block diagrams illustrating an example of an autonomous driving simulation platform 401 of an ADV according to one embodiment. The safety and reliability of an ADV require massive functional and performance tests, which are expensive and time consuming if these tests were conducted using physical vehicles on roads. A simulation platform 401 may be used to perform these tasks less costly and more efficiently.

In one embodiment, the simulation platform 401 may include a dynamic model 402 of the ADV (e.g., the ADV 101 including the ADS 110 as illustrated in FIGS. 1, 3A-3B), a game-engine based simulator 406, and a record file player 408. The game-engine based simulator 405 can provide a 3D virtual world where sensors can perceive and provide precise ground truth data for every piece of an environment. The record file player 408 can replay record files recorded in the real world for use in testing the functions and performance of various modules of the dynamic model 402.

In one embodiment, the ADV dynamic model 402 can be a virtual vehicle that includes a number of core software modules, including the localization module 301, the perception module 302, the prediction module 303, the planning module 305, the control module 306. These functions of these modules are described in detail in FIGS. 3A-3B.

As further shown, the simulation platform 401 can include a guardian module 417, which is a safety module that performs the function of an action center and intervenes when a monitor 425 detects a failure. When all modules work as expected, the guardian module 417 allows the flow of control to work normally. When a crash in one of the modules is detected by the monitor 425, the guardian module 427 can bring the ADV dynamic model 402 to a stop.

The simulation platform 401 can include a human machine interface (HMI) 427, which is a module for viewing the status of the dynamic model 402, and controlling the dynamic model 402 in real time.

Referring to FIG. 4B, the simulation platform 401 includes an evaluation module 430 configured to evaluate the performance of the planning module 305. At the simulation platform 401, the prediction module 303 predicts the trajectories of the obstacles based on the map, the histories of the obstacles and the interactions of the obstacles. The planning module 305 plans the trajectory of the ADV, as well as driving parameters (e.g., distance, speed, and/or turning angle), according to the trajectories of the obstacles, the driving environment (such as the map, routing information, traffic light) and the state of the ADV. The performance of the planning module 305 depends on the results of the prediction module 303, because the planning module 305 needs the trajectories of the obstacles to generate the trajectory of the ADV 101.

The evaluation module 430 may evaluate the performance of the planning module 305. The evaluation module 430 may be considered as a function of the trajectory of the ADV (tau), which may be evaluated based on a set of metrics. For example, the evaluation module 430 may evaluate the planned trajectory of the ADV in current environment based on the set of metrics. For example, the set of metrics may include collision, comfort, violation of traffic rules, near collision, etc.

In one embodiment, the evaluation module 430 may include a metric module 431 and a score module 436. The metric module 431 may include a collision module 432, a comfort module 433, a traffic rule module 434, and a near collision module 435. The collision module 432 is configured to determine whether the outputs from the planning module, e.g., the planned trajectory, would result in a collision of the ADV. The comfort module 433 may be configured to determine a comfort level of the trajectory of the ADV. For example, the comfort level may be determined based on the number of hard brakes, acceleration of the ADV, etc. The near collision module 435 may be configured to determine whether there is a near collision of the ADV with the obstacles. The traffic law module 434 is configured to determine whether the outputs from the planning module, e.g., the planned trajectory, has a traffic law violation including a traffic light violation, a speed limit violation, or a lane changing guideline violation. For example, the traffic law module 434 may check whether the ADV keeps certain safety distance during a lane-follow scenario, whether there is not a rear-end collision during an emergency stop, whether the ADV follows lane changing guideline, whether there are no red or yellow light violations, or whether there are no speed limit violations.

The score module 436 may be configured to determine an overall score or combination score of the performance of the planning module 305. For example, each of the collision module 432, the comfort module 433, the traffic rule module 434, the near collision module 435 may determine a score of the performance of the planning module 305 according to a corresponding metric. The collision module 432 may determine a score with respect to collision. The comfort module 432 may determine a score with respect to comfort. The traffic rule module 434 may determine a score with respect to traffic rules. The near collision module 435 may determine a score with respect to near collision. Then, the score module 436 generate the overall score or combination score based on all of the scores, including the score with respect to collision, the score with respect to comfort, the score with respect to traffic rules, and the score with respect to near collision.

In one example, the evaluation module 430 for the planning module of the ADV may include a hybrid version of performance evaluation or critic. The evaluation module 430 may include both a traffic rule based evaluation and a machine learning based evaluation of the performance of the planning module. The evaluation module 430 may include a machine learning (ML) model (not shown). The ML learning module may include a deep learning model which may be trained with any neuron network. The ML learning module may be based on the data of the driving environment and the outputs from the planning module. This data-driven ML learning module may assume human driving is the desired behavior. The ML learning module may be trained to focus on learning trajectories from experts, e.g., human drivers. The closer the outputs of the planning module to the human drivers, the better the performance of the planning module, and the lower the score of the planning module.

The evaluation module 430 may include more or less modules. For example, modules 431-436 may be installed in a persistent storage device, loaded into a memory, and executed by one or more processors (not shown). Note that some or all of these modules may be communicatively coupled to or integrated. Some of modules 431-436 may be integrated together as an integrated module.

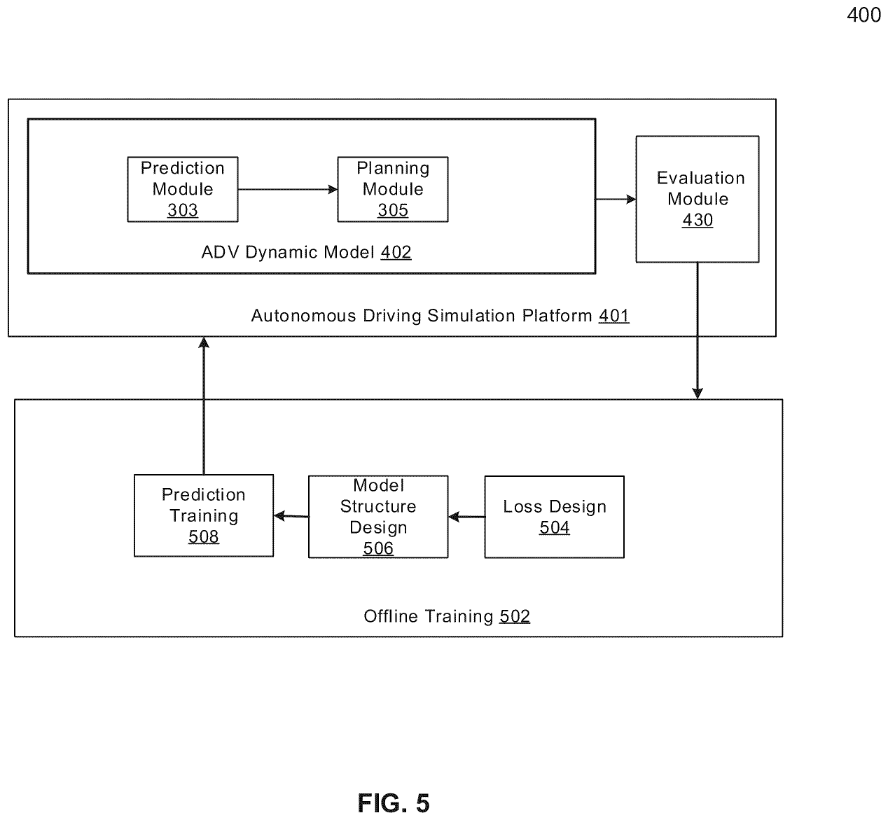

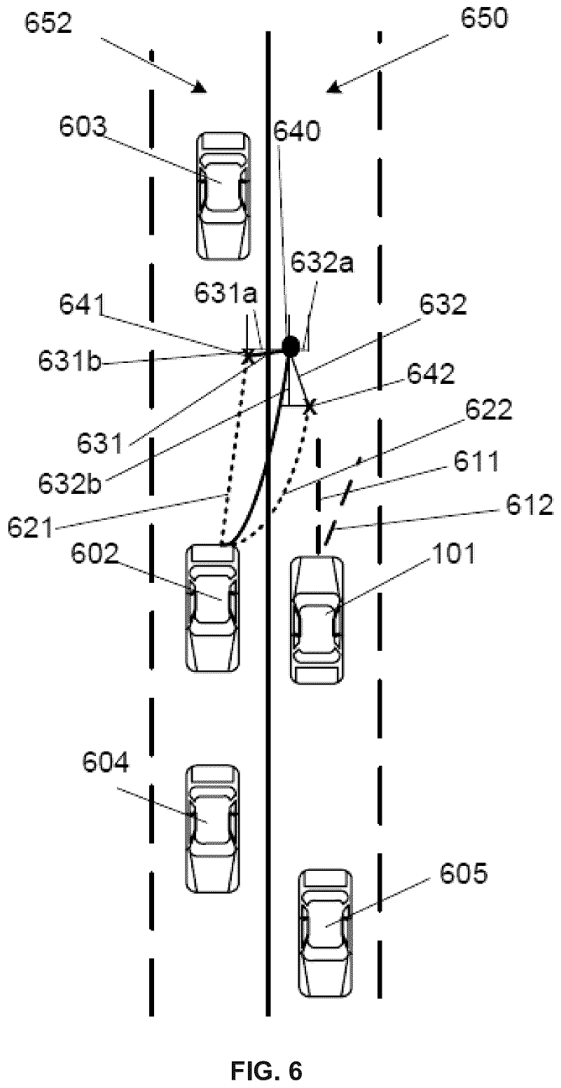

FIG. 5 is a block diagram illustrating an example of a process of evaluating the prediction module 303 of the ADV 101 at the autonomous driving simulation platform 401 according to one embodiment. FIG. 6 is a diagram illustrating an example of evaluating the prediction module 303 according to one embodiment. Referring to FIGS. 5-6, the prediction module 303 serves the planning module 305. Thus, only measuring the accuracy of the predicated trajectories of the obstacles compared to the ground truth may not benefit the planning module 305. In order to improve the overall performance of the ADV, the performance of the prediction module is evaluated based on the performance of the planning module. In this way, the overall performance of the ADV is improved with the improvement of the performance of the prediction module, thereby improving the safety and reliability of the ADV.

Referring to FIG. 6, the ADV 101 may be driving on a lane 650. Multiple obstacles 602, 603, 604, 605 may be driving near the ADV 101 on an adjacent lane 652 or behind the ADV on the lane 650. As an example, obstacles 602, 603, 604, 605 may be moving vehicles such as cars, trucks, buses, motorcycles, etc. The prediction module 303 may predict multiple trajectories for the multiple obstacles 602, 603, 604, 605. For example, the prediction module 303 may predict a trajectory 621 or trajectory 622 of the obstacle 602. Based on the trajectory 621 or trajectory 622 of the obstacle 602, the planning module 305 may plan a trajectory 611 or 612 for the ADV 101.

Currently, the performance of the prediction module 303 is evaluated only based on a Euclidean distance error from a predicted location of the obstacle to a ground truth location (e.g., obtained by record files). However, improving the accuracy of the Euclidean distance error may not contribute to a better performance of the planning module. For example, as illustrated in FIG. 6, the Euclidean distance error 631 (from a predicted location 641 of the obstacle 602 to a ground truth location 640) for the predicted trajectory 621 is smaller than the Euclidean distance error 632 (from a predicted location 642 of the obstacle 602 to the ground truth location 640) for the predicted trajectory 622. Based on the predicted trajectory 621, the obstacle 602 would not cut into the lane 650 following the predicted trajectory 621. Thus, the planning module 305 may plan the trajectory 611 of the ADV to continue to go straight along the lane 650. Then, the ADV 101 would collide with the obstacle 602, or have to use a hard brake to be near a collision with the obstacle 602. In this scenario, the planning module 305 may have a poor performance, and the planning trajectory 611 of the ADV may have a bad score indicating the poor performance.

A new evaluation system for evaluating the performance of the prediction module based on the performance of the planning module will improve the overall performance of the ADV. For example, based on the predicted trajectory 622, the obstacle 602 may cut into move into the lane 650 from the lane 652 following the predicted trajectory 622. Thus, the planning module 305 may plan the trajectory 612 of the ADV to move away from the obstacle 602, make a lane change and/or slow down to prepare for an emergency stop. Then, the ADV 101 would not collide with the obstacle 602, nor have to use a hard brake. In this scenario, the planning module 305 may have a good performance, and the planning trajectory 612 of the ADV may have a good score indicating the good performance. Therefore, the predicted trajectory 622 may have a better performance of the predicted trajectory 621.

Referring back to FIG. 5, the performance of the ADV 101, including the prediction module 303 and the planning module 305, may be simulated at the autonomous driving simulation platform 401. At the simulation platform 401, the prediction module 303 may predict the multiple trajectories of the multiple obstacles 602, 603, 604, 605. Based on the multiple trajectories of the multiple obstacles, the planning module 305 may plan a trajectory (e.g., 611 or 612) of the ADV 101. The evaluation module 430 may evaluate the performance of the trajectory (e.g., 611 or 612) of the ADV 101. For example, the evaluation module 430 may evaluate the performance of the trajectory (e.g., 611 or 612) of the ADV 101 based on the set of metrics, as described with connection to FIGS. 4A-4B.

After the information based on the performance of the planning module 305, including the feedback or the simulation results, from the evaluation module 430 is received, the performance of the prediction module 303 may be improved, at offline training 502. For example, a loss function of an analysis model of the prediction module 303 may be designed according the information of the evaluation module 430, as illustrated at block 504. The analysis model may analyze the performance of the prediction module based on the simulation performance of the planning module. For another example, a model structure of the analysis model of the prediction module 303 may be designed according the information of the evaluation module 430, as illustrated at block 506. As an example, the loss function is an objective function of an analysis model of the prediction module, which is used to guide the design and/or the training of the prediction module. The loss function is to be minimized when designing and/or training the prediction module. The training process of the prediction module is to achieve a lower loss.

Referring to FIGS. 5-6, in one embodiment, instead of using just a Euclidean distance error, the loss function may be designed to include a weighted lateral distance error and a weighted longitudinal distance error from the ground truth to the predicted location. The Euclidean distance error from the ground truth to the predicted location may be decomposed to the lateral distance error and the longitudinal distance error from the ground truth to the predicted location. As illustrated in FIG. 6, for the predicted trajectory 622, the Euclidean distance error 632, from the ground truth 640 to the predicted location 642, may be decomposed to a lateral distance error 632a and a longitudinal distance error 632b; for the predicted trajectory 621, the Euclidean distance error 632, from the ground truth 640 to the predicted location 641, may be decomposed to a lateral distance error 631a and a longitudinal distance error 631b. For example, the lateral distance error (e.g., 631a or 632a) may be weighted larger than the longitudinal distance error (e.g., 631b, 632b) because the lateral distance error may have more impact to the performance of the planning module 305 (e.g., the planned trajectory of the ADV). More accurate prediction of the lateral distance error (e.g., 631a or 632a) may improve the planned trajectory (e.g., 611, or 612) of the ADV. The loss function may include a composite distance error based on the weighted lateral distance error and the weighted longitudinal distance error from the ground truth to the predicted location, where the weighting of the lateral distance error is larger than the weighting of the longitudinal distance error. For example, the loss function may be expressed as:

Loss=W1*lateral distance error+W2*longitudinal distance error,

wherein W1 is the weighting of the lateral distance error, and W2 is the weighting of the longitudinal distance error.

In one embodiment, the model structure of the analysis model of the prediction module 303 may be changed to improve the performance of the planning module. As illustrated in FIG. 6, there may be multiple obstacles 602, 603, 604, 605 near or around the ADV 101. It might take too much time and computing resources to accurately predict every obstacle. For example, the prediction module and the planning module might need to be refreshed every 0.1 second. Some of the obstacles may not have much impact to the planning module 305, thus, it may not necessary to pay high attention to some of the obstacles near or around the ADV 101, while some obstacles may need close attention to. As illustrated in FIG. 6, as an example, the obstacle 602 on the adjacent lane 652 close to the ADV 101 may need close attention, because the obstacle 602 may cut into (or enter) the lane 650 and result in a collision with the ADV 101. As another example, the obstacle 605 behind the ADV 101 may not need much attention, because the obstacle 605 may not have little impact with the trajectory of the ADV 101.

An attention layer may be added to the analysis model prediction module 303. The analysis model may have a layered approach with multiple layers including the attention layer. For example, the obstacles which may have more impact to the planning module (e.g., the trajectory of the ADV 101) may be placed in the attention layer. The prediction module 303 may select one or more obstacles, which may have more impact to the planning module, from the multiple obstacles near or around the ADV 101. For example, as illustrated in FIG. 6, the ADV 101 is driving on the lane 650, e.g., a straight lane, with adjacent lane 652 on the left, and there are obstacles driving on the adjacent lane 652. The obstacle 602 driving on the adjacent lane 652 close to the ADV 101 may be selected to be placed in the attention layer, because the obstacle 602 may cut into (or enter) the lane 650 and result in a collision with the ADV 101. As another example, the obstacle 605 behind the ADV 101 may not be selected to be placed in the attention layer, because the obstacle 605 may not have little impact with the trajectory of the ADV 101. The prediction module may pay more attention to the selected obstacles in the attention layer. The prediction module may predict the corresponding trajectories of the selected obstacles chosen by the attention layer with an accuracy higher than an accuracy of trajectories of other obstacles not selected by the attention layer. In one embodiment, the prediction module may predict the trajectories of other obstacles not selected by the attention layer with a lower accuracy. In one embodiment, the prediction module may ignore the trajectories of other obstacles not in the attention layer.

In addition, if the loss function is changed, as discussed above, the analysis model of the prediction module may not be able to achieve the desired loss. For example, the loss function may need to be smaller than a predetermined threshold, however, the analysis model of the prediction module may have limited capacity to achieve the predetermined threshold. By adding the attention layer, the capacity of the analysis model of the prediction module is increased. Thus the analysis model of the prediction module is able to minimize the loss function to achieve the desired loss is increased.

At block 508, the prediction module 303 may be trained using the loss function designed at the block 504 and the model structure designed/changed at the block 506. Then, at the simulation platform 401, the prediction module 303 may predict the trajectories of the obstacles. Then, and the planning module may plan the trajectory of the ADV. The simulation results of the planning module may be evaluated at the evaluation module 430. If the planning module is improved, e.g., the planned trajectory of the ADV is improved, based on the set of evaluation metrics discussed above, the loss function design and the model structure design/change is in a right direction; otherwise, the loss function design and the model structure design/change is not in a right direction. Based the simulation results of the planning module, the loss function of the analysis model of the prediction module may be tuned or redesigned at the block 504 again. The model structure of the analysis model of the prediction module may be tuned or redesigned at the block 506 again. Afterwards, the prediction module 303 may be further tuned or retrained to further improve the performance of the planning module. This may be an iterated process with multiple cycles. When the performance of the planning module is maximized, the prediction module 303 is ready to be deployed to the ADV 101 to drive autonomously on the road.

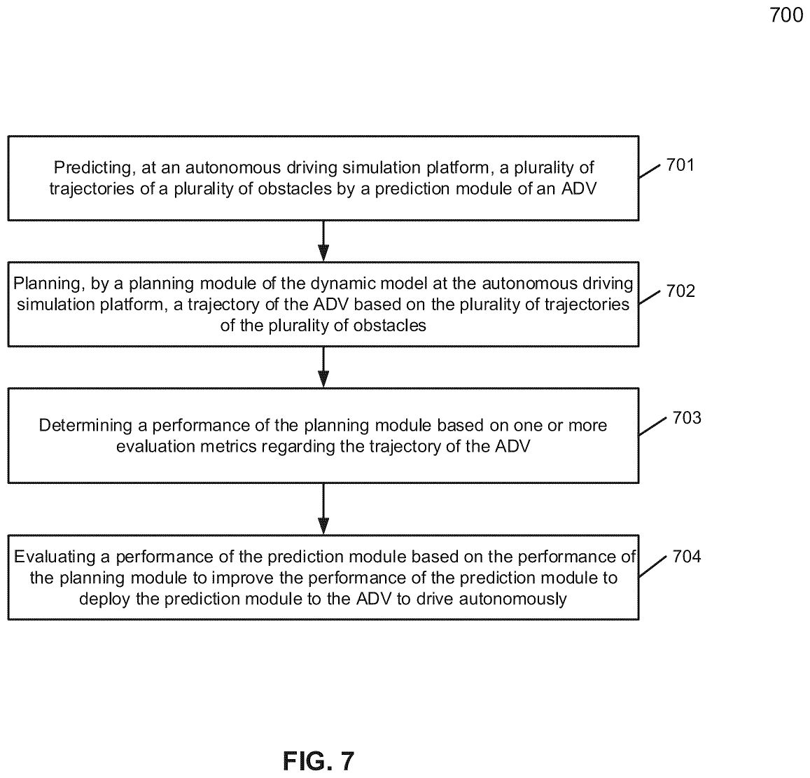

FIG. 7 is a flow diagram illustrating a method of evaluating a prediction module of the ADV 101 according to one embodiment. Method 700 may be performed by processing logic which may include software, hardware, or a combination thereof. Referring to FIG. 7, in operation 701, processing logic predicts, at an autonomous driving simulation platform, a plurality of trajectories of a plurality of obstacles by a prediction module of an ADV.

In operation 702, processing logic plans, at the autonomous driving simulation platform, a trajectory of the ADV by a planning module of the ADV based on the plurality of trajectories of the plurality of obstacles.

In operation 703, processing logic determines, at the autonomous driving simulation platform, a performance of the planning module based on one or more evaluation metrics regarding the trajectory of the ADV.

In one embodiment, the one or more evaluation metrics regarding the trajectory of the ADV include a collision of the ADV with one of the plurality of obstacles, a comfort level of the trajectory of the ADV, a violation of traffic laws of the trajectory of the ADV.

In one embodiment, processing logic may determine one or more scores according to the one or more evaluation metrics. Each of the one or more scores may correspond to an evaluation metric of the one or more evaluation metrics. Processing logic may determine an overall score of the performance of the planning module based on the one or more scores.

In operation 704, processing logic evaluates a performance of the prediction module based on the performance of the planning module to improve the performance of the prediction module to deploy the prediction module to the ADV to drive autonomously.

In one embodiment, processing logic may determine a loss function of an analysis model of the prediction module based on the performance of the planning module.

In one embodiment, the loss function includes a composite distance error based on a weighted lateral distance error and a weighted longitudinal distance error from a ground truth to a predicted location, where a weighting of the lateral distance error is larger than a weighting of the longitudinal distance error.

In one embodiment, processing logic may change a structure of the analysis model of the prediction module based on the performance of the planning module.

In one embodiment, processing logic may add an attention layer, and select one or more obstacles from the plurality of obstacles and place the one or more obstacles in the attention layer.

In one embodiment, processing logic may predict one or more trajectories of the one or more obstacles with an accuracy higher than an accuracy of trajectories of other obstacles not in the attention layer.

In one embodiment, processing logic may train the prediction module based on an analysis model to improve the performance of the prediction module.

Note that some or all of the components as shown and described above may be implemented in software, hardware, or a combination thereof. For example, such components can be implemented as software installed and stored in a persistent storage device, which can be loaded and executed in a memory by a processor (not shown) to carry out the processes or operations described throughout this application. Alternatively, such components can be implemented as executable code programmed or embedded into dedicated hardware such as an integrated circuit (e.g., an application specific IC or ASIC), a digital signal processor (DSP), or a field programmable gate array (FPGA), which can be accessed via a corresponding driver and/or operating system from an application. Furthermore, such components can be implemented as specific hardware logic in a processor or processor core as part of an instruction set accessible by a software component via one or more specific instructions.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments of the disclosure also relate to an apparatus for performing the operations herein. Such a computer program is stored in a non-transitory computer readable medium. A machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g. circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments of the present disclosure are not described with reference to any particular programming language. It will be appreciated that a variety of programming languages may be used to implement the teachings of embodiments of the disclosure as described herein.

In the foregoing specification, embodiments of the disclosure have been described with reference to specific exemplary embodiments thereof. It will be evident that various modifications may be made thereto without departing from the broader spirit and scope of the disclosure as set forth in the following claims. The specification and drawings are, accordingly, to be regarded in an illustrative sense rather than a restrictive sense.

What is claimed is:

1. A computer-implemented method, comprising:
predicting, at an autonomous driving simulation platform, a plurality of trajectories of a plurality of obstacles by a prediction module of an autonomous driving vehicle (ADV);
planning, at the autonomous driving simulation platform, a trajectory of the ADV by a planning module of the ADV based on the plurality of trajectories of the plurality of obstacles;
determining, at the autonomous driving simulation platform, a performance of the planning module based on one or more evaluation metrics regarding the trajectory of the ADV; and
evaluating a performance of the prediction module based on the performance of the planning module to improve the performance of the prediction module to deploy the prediction module to the ADV to drive autonomously.

2. The method of claim 1, wherein the one or more evaluation metrics regarding the trajectory of the ADV include a collision of the ADV with one of the plurality of obstacles, a comfort level of the trajectory of the ADV, a violation of traffic laws of the trajectory of the ADV.

3. The method of claim 1, wherein the determining, at the autonomous driving simulation platform, the performance of the planning module based on one or more evaluation metrics comprises
determining one or more scores according to the one or more evaluation metrics, each of the one or more scores corresponds to an evaluation metric of the one or more evaluation metrics; and
determining an overall score of the performance of the planning module based on the one or more scores.

4. The method of claim 1, further comprising:
determining a loss function of an analysis model of the prediction module based on the performance of the planning module.

5. The method of claim 4, wherein the loss function includes a composite distance error based on a weighted lateral distance error and a weighted longitudinal distance error from a ground truth to a predicted location, where a weighting of the lateral distance error is larger than a weighting of the longitudinal distance error.

6. The method of claim 1, further comprising
changing a structure of an analysis model of the prediction module based on the performance of the planning module.

7. The method of claim 6, wherein the changing the structure of the analysis model of the prediction module based on the performance of the prediction module comprises
adding an attention layer to select one or more obstacles from the plurality of obstacles.

8. The method of claim 7, wherein the predicting, at the autonomous driving simulation platform, the plurality of trajectories of the plurality of obstacles comprises predicting one or more trajectories of the one or more obstacles selected by the attention layer with an accuracy higher than an accuracy of trajectories of other obstacles not selected by the attention layer.

9. The method of claim 1, further comprising
training the prediction module based on an analysis model to improve the performance of the prediction module.

10. A non-transitory machine-readable medium having instructions stored therein, which when executed by a processor, cause the processor to:
predict, at an autonomous driving simulation platform, a plurality of trajectories of a plurality of obstacles by a prediction module of an autonomous driving vehicle (ADV);
plan, at the autonomous driving simulation platform, a trajectory of the ADV by a planning module of the ADV based on the plurality of trajectories of the plurality of obstacles;
determine, at the autonomous driving simulation platform, a performance of the planning module based on one or more evaluation metrics regarding the trajectory of the ADV; and
evaluate a performance of the prediction module based on the performance of the planning module to improve the performance of the prediction module to deploy the prediction module to the ADV to drive autonomously.

11. The non-transitory machine-readable medium of claim 10, wherein the one or more evaluation metrics regarding the trajectory of the ADV include a collision of the ADV with one of the plurality of obstacles, a comfort level of the trajectory of the ADV, a violation of traffic laws of the trajectory of the ADV.

12. The non-transitory machine-readable medium of claim 10, wherein the processor is further to
determine one or more scores according to the one or more evaluation metrics, each of the one or more scores corresponds to an evaluation metric of the one or more evaluation metrics; and
determine an overall score of the performance of the planning module based on the one or more scores.

13. The non-transitory machine-readable medium of claim 10, wherein the processor is further to
determine a loss function of an analysis model of the prediction module based on the performance of the planning module.

14. The non-transitory machine-readable medium of claim 13, wherein the loss function includes a composite distance error based on a weighted lateral distance error and a weighted longitudinal distance error from a ground truth to a predicted location, where a weighting of the lateral distance error is larger than a weighting of the longitudinal distance error.

15. The non-transitory machine-readable medium of claim 10, wherein the processor is further to
change a structure of an analysis model of the prediction module based on the performance of the planning module.

16. The non-transitory machine-readable medium of claim 15, wherein the processor is further to
add an attention layer to select one or more obstacles from the plurality of obstacles.

17. The non-transitory machine-readable medium of claim 16, wherein the processor is further to predict one or more trajectories of the one or more obstacles selected by the attention layer with an accuracy higher than an accuracy of trajectories of other obstacles not selected by the attention layer.

18. The non-transitory machine-readable medium of claim 10, wherein the processor is further to train the prediction module based on an analysis model to improve the performance of the prediction module.

19. A data processing system, comprising:
a processor; and
a memory coupled to the processor to store instructions, which when executed by the processor, cause the processor to:
predict, at an autonomous driving simulation platform, a plurality of trajectories of a plurality of obstacles by a prediction module of an autonomous driving vehicle (ADV);
plan, at the autonomous driving simulation platform, a trajectory of the ADV by a planning module of the ADV based on the plurality of trajectories of the plurality of obstacles;
determine, at the autonomous driving simulation platform, a performance of the planning module based on one or more evaluation metrics regarding the trajectory of the ADV; and
evaluate a performance of the prediction module based on the performance of the planning module to improve the performance of the prediction module to deploy the prediction module to the ADV to drive autonomously.

20. The data processing system of claim 19, wherein the processor is further to
determine a loss function of an analysis model of the prediction module based on the performance of the planning module.
